(19) United States
(12) Patent Application Publication
(10) Pub. No.: US 2024/0016060 A1
(43) Pub. Date: Jan. 11, 2024

(54) SELECTIVE LASER PATTERNING ON PIEZOELECTRIC THIN FILMS FOR PIEZOELECTRIC DEVICE FABRICATION

(71) Applicant: Applied Materials, Inc., Santa Clara, CA (US)

(72) Inventors: Vijay Bhan SHARMA, Mumbai (IN); Nilesh PATIL, Mumbai (IN); Bharatwaj RAMAKRISHNAN, Sunnyvale, CA (US); Suresh Chand SETH, Mumbai (IN); Abhijeet Laxman SANGLE, Mumbai (IN)

(21) Appl. No.: 18/218,409

(22) Filed: Jul. 5, 2023

Related U.S. Application Data
(60) Provisional application No. 63/368,125, filed on Jul. 11, 2022.

(51) Int. Cl. H10N 30/076; H10N 30/853; H10N 30/06

(52) U.S. Cl. CPC H10N 30/076; H10N 30/8554; H10N 30/06

(57) ABSTRACT

Examples disclosed herein relate to piezoelectric devices and methods of patterning piezoelectric layers for piezoelectric device fabrication. In certain embodiments, a piezoelectric layer disposed over a bottom electrode layer on a substrate is selectively etched via a laser etching process to expose portions of the bottom electrode layer. The laser etching process of the piezoelectric layer facilitates improvement of throughput and reduces hazardous byproduct production during fabrication of piezoelectric devices.

### CROSS-REFERENCE TO RELATED APPLICATIONS

This application claims priority to U.S. Provisional Patent Application Ser. No. 63/368,125, filed on Jul. 11, 2022, which is herein incorporated by reference.

### BACKGROUND

### Field

Embodiments of the present disclosure generally relate to piezoelectric devices. More specifically, embodiments disclosed herein relate to piezoelectric devices and methods of patterning piezoelectric layers for piezoelectric device fabrication.

### Description of the Related Art

Piezoelectric materials, which are materials that accumulate electric charge upon application of mechanical stress, are frequently used in sensors and transducers for piezoelectric devices such as gyro-sensors, ink-jet printer heads, ultrasound technology, and other microelectromechanical systems (MEMS) devices, including acoustic resonators for mobile phones and other wireless electronics. Patterning the piezoelectric materials during fabrication of the piezoelectric devices can be difficult due to the brittle properties of the piezoelectric materials.

Accordingly, what is needed in the art are improved selective patterning methods of piezoelectric materials.

### SUMMARY

In one embodiment, a method of forming a piezoelectric device includes disposing a bottom electrode layer over a substrate via physical vapor deposition (PVD), disposing a piezoelectric layer over the bottom electrode layer via PVD, forming a top electrode layer with a top electrode pattern over the piezoelectric layer, and etching the piezoelectric layer via laser etching to form exposed portions of the bottom electrode layer to form the piezoelectric device.

In another embodiment, a method of forming a piezoelectric device includes disposing a bottom electrode layer over a substrate via physical vapor deposition (PVD) and disposing a piezoelectric layer over the bottom electrode layer via PVD. The piezoelectric layer includes an aluminum nitride (AlN), scandium-doped aluminum nitride (ScAlN) material. The method further includes forming a top electrode layer with a top electrode pattern over the piezoelectric layer and etching the piezoelectric layer via laser etching to form exposed portions of the bottom electrode layer. The laser etching occurs with an etch rate of about 100 μm/min to about 10 μm/min.

In yet another embodiment, a piezoelectric device is provided. The piezoelectric device includes a substrate, a bottom electrode layer formed over the substrate, and a piezoelectric layer formed over the bottom electrode layer. The piezoelectric layer includes an aluminum nitride (AlN) or scandium-doped aluminum nitride (ScAlN) material. Exposed portions of the bottom electrode layer are formed via laser etching the piezoelectric layer. The piezoelectric device further includes a top electrode layer formed on the piezoelectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, and may admit to other equally effective embodiments.

FIG. 1 is a schematic, top view of a piezoelectric device, according to embodiments described herein

FIG. 2 is a schematic cross-sectional view of a laser etching system according to embodiments described herein.

FIG. 3 is a flow diagram of a method of forming a piezoelectric device, as shown in FIGS. 4A-4D, according to embodiments described herein.

FIGS. 4A-4D are schematic, side views of a substrate during the method of forming a piezoelectric device, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to piezoelectric devices. More specifically, embodiments disclosed herein relate to piezoelectric devices and methods of patterning piezoelectric layers for piezoelectric device fabrication.

Patterning a piezoelectric material in piezoelectric devices can be challenging due to the brittle and hard characteristics of the piezoelectric material. For piezoelectric devices, it is critical to pattern the piezoelectric material without damaging a bottom electrode. An improvement in patterning the piezoelectric material can be achieved through the methods disclosed herein. The methods disclosed herein enable patterning of the piezoelectric material with increased throughput and reduction of toxic chemical release. In certain examples, a laser etching system is utilized to pattern the piezoelectric material. For example, the laser etching system includes laser process tuning to adjust parameters of the laser to improve patterning performance and throughput.

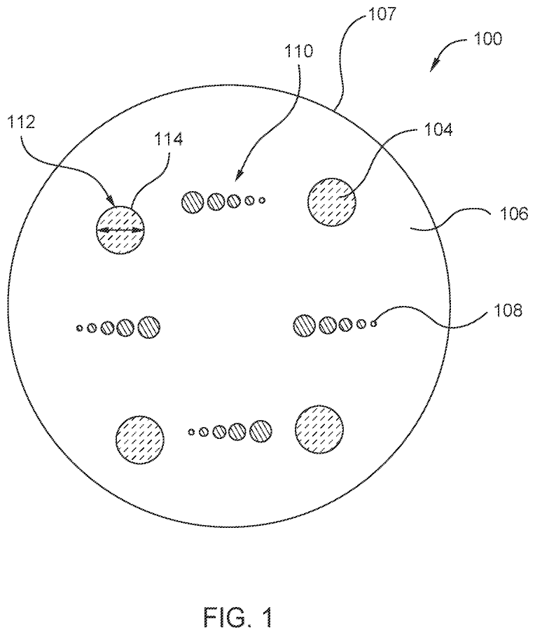

FIG. 1 is a schematic, top view of a piezoelectric device 100, according to embodiments described herein. The piezoelectric device 100 may be fabricated according to the methods described herein. The piezoelectric device 100 shown in FIG. 1 may be partially fabricated and may require other processing steps to form a functional device. The piezoelectric device 100 may be utilized for sensing applications (e.g., gyro-sensors), ultrasound technology, ink-jet printing, or microelectromechanical systems (MEMS) devices, including acoustic resonators for mobile phones and other wireless electronics.

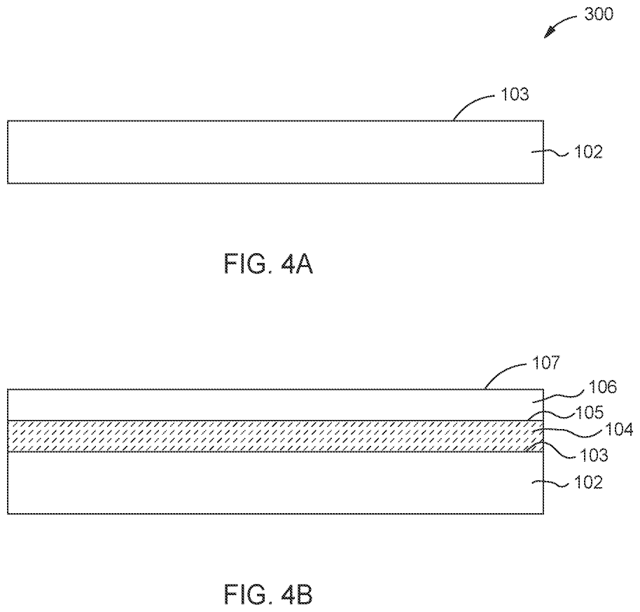

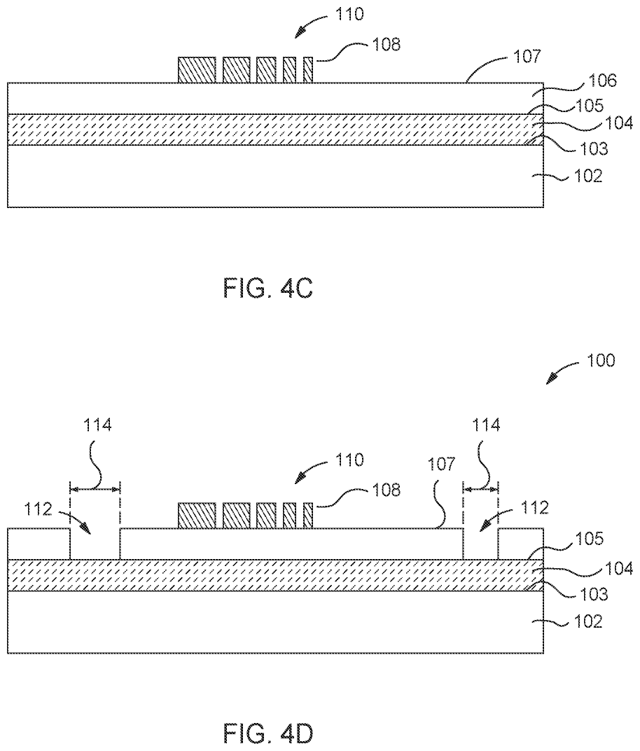

The piezoelectric device 100 includes a substrate 102 (shown in FIGS. 4A-4D), a bottom electrode layer 104, a piezoelectric layer 106, and a top electrode layer 108. The substrate 102 may have a diameter in a range from about 100 mm to about 750 mm and may be formed from a variety of materials, including silicon (Si), silicon carbide (SiC), SiC-coated graphite, or silicon oxide (SiO₂). In one example, the substrate 102 has a surface area of about 1,000 cm² or more. In another example, the surface area of the substrate 102 may be about 2,000 cm² or more, and about 4,000 cm² or more.

The bottom electrode layer 104 is disposed over a substrate surface 103 (shown in FIGS. 4A-4D) of the substrate 102. The bottom electrode layer 104 is configured to be a bottom electrode for the piezoelectric device 100. Examples of suitable materials for the bottom electrode layer 104 include platinum (Pt), molybdenum (Mo), SrRuO3, LaNiO3, CaRuO3, LaSrMnO3, and the like. The bottom electrode layer 104 may have a thickness between about 25 nm and about 200 nm. The bottom electrode layer 104 may have a thickness between about 50 nm and about 200 nm, such as between about 75 nm and about 175 nm, such as between about 100 nm and about 150 nm, for example, about 125 nm.

The piezoelectric layer 106 is disposed over a bottom electrode surface 105 (shown in FIGS. 4A-4D) of the bottom electrode layer 104. In certain embodiments, the piezoelectric layer 106 is formed of one or more layers containing one or more of aluminum nitride (AlN), scandium-doped aluminum nitride (ScAlN), lead zirconate titanate (PZT), lead magnesium niobate-lead titanate (PMN-PT), or LiNbO₃ (LNO). The piezoelectric layer 106 may have a thickness between about 300 nm and about 2000 nm, such as between about 750 nm and about 1500 nm, such as about 1000 nm. In some embodiments, which can be combined with other embodiments described herein, the thickness of the piezoelectric layer can vary across the bottom electrode surface 105. In other embodiments, which can be combined with other embodiments described herein, the thickness of the piezoelectric layer is constant across the bottom electrode surface 105. The piezoelectric layer 106 is selectively etched via a laser etching process to form exposed portions 112 of the bottom electrode layer 104. The exposed portions 112 allow access to the bottom electrode layer 104. The laser etching process is described below in method 300. An exposed portion length 114 is defined by the size of exposed portions 112.

The top electrode layer 108 is disposed over a piezoelectric surface 107 of the piezoelectric layer 106. The top electrode layer 108 is configured to be a top electrode for finished piezoelectric devices. In certain examples, the top electrode layer 108 is formed of the same or different material than the bottom electrode layer 104. Examples of suitable materials for the bottom electrode layer 104 include platinum (Pt), molybdenum (Mo), SrRuO3, LaNiO3, CaRuO3, LaSrMnO3, and the like. The top electrode layer 108 may have a thickness between about 30 nm and about 200 nm, such as between about 50 nm and about 150, for example, about 100 nm.

As shown in FIG. 1, the top electrode layer 108 may be patterned as desired on the piezoelectric surface 107. The top electrode layer 108 is formed with a top electrode pattern 110. The top electrode pattern 110 may be pre-determined prior to fabrication in order to meet the specifications of the piezoelectric device 100. The top electrode pattern 110 of the top electrode layer 108 is not limited to the pattern shown in FIG. 1 and may be adjusted as desired. For example, the top electrode pattern 110 can include circular, rectangular, square, or irregular patterns.

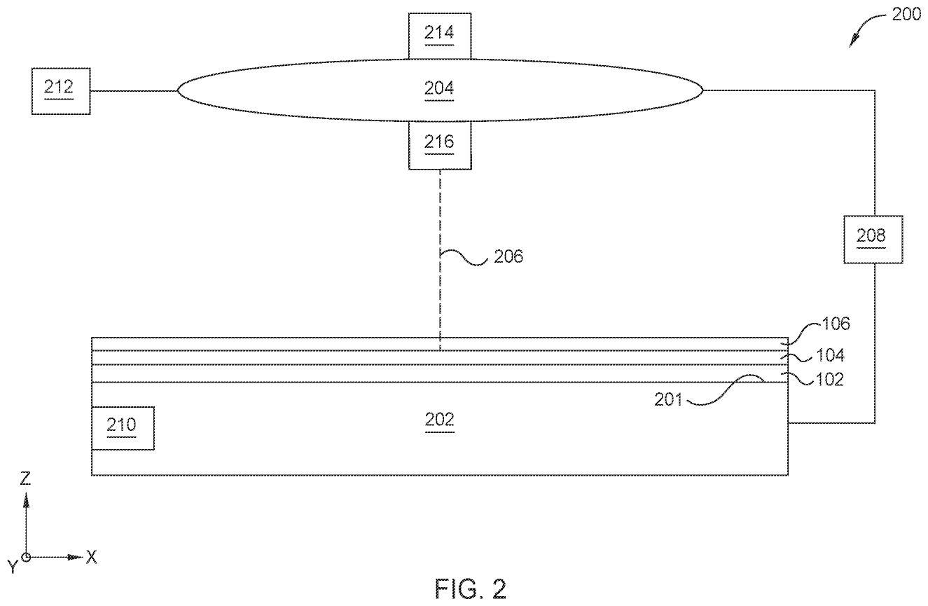

FIG. 2 is a schematic, cross-sectional view of a laser etching system 200. The laser etching system is utilized in a method 300 for patterning a piezoelectric layer with the laser etching system 200 during the fabrication of the piezoelectric device 100, as shown in FIGS. 4A-4D.

The laser etching system 200 includes the substrate 102 disposed on a surface 201 of a stage 202. The substrate 102 also may include the bottom electrode layer 104 and the piezoelectric layer 106 disposed thereon. In some embodiments, the top electrode layer 108 is also disposed on the bottom electrode layer 104.

The stage 202 is disposed in the laser etching system 200 such that the surface 201 of the stage 202 is positioned opposite a scanner 204. The scanner 204 includes a laser source 214, an optical array 216, and a laser 206 disposed from the optical array 216. The laser etching system 200 is operable to etch the piezoelectric layer 106 to expose the bottom electrode layer 104. The laser etching system 200 is operable to provide a laser pulse towards the substrate 102 such that the piezoelectric layer 106 is etched. The laser etching system 200 includes a controller 208. The controller 208 is in communication with the stage 202 and the scanner 204.

The controller 208 is generally designed to facilitate the control and automation of the method described herein. The controller 208 may be coupled to or in communication with the laser source 214, the optical array 216, the stage 202, and the scanner 204. The stage 202 and the scanner 204 may provide information to the controller 208 regarding the method 300 and alignment of the substrate 102. The controller 208 may be in communication with or coupled to a CPU (i.e., a computer system). The CPU can be a hardware unit or combination of hardware units capable of executing software applications and processing data. In some configurations, the CPU includes a central processing unit (CPU), a digital signal processor (DSP), an application-specific integrated circuit (ASIC), a graphic processing unit (GPU) and/or a combination of such units. The CPU is generally configured to execute the one or more software applications and process stored media data. The controller 208 may include a non-transitory computer-readable medium for storing instructions of forming a dicing path along a substrate as described herein. The non-transitory computer-readable medium may be a part of the CPU.

The laser 206 is an optical fiber laser. In one embodiment, which can be combined with other embodiments described herein, the laser 206 includes a Gaussian beam profile. In another embodiment, which can be combined with other embodiments described herein, the laser 206 is an ultra-violet (UV) laser. In another embodiment, which can be combined with other embodiments described herein, the laser 206 is an infrared laser. In another embodiment, which can be combined with other embodiments described herein, the laser 206 is a Bessel-type beam profile. In yet other embodiments, the laser 206 is a multi-focus laser and uses a bifocal lens as part of the optical array 216. Multiple lenses may also be used within the optical array 216 to diffract the laser 206 and form multiple focal points within the substrate 102. The laser 206 is in communication with the controller 208. The controller 208 may control other input parameters or output parameters of the laser 206, as described in the method 300.

The stage 202 includes a stage actuator 210. The stage actuator 210 allows the stage 202 to scan in the X direction, the Y direction, and the Z direction, as indicated by the coordinate system shown in FIG. 2. The stage 202 is coupled to the controller 208 in order to provide information of the location of the stage 202 to the controller 208. Additionally, the stage 202 is in communication with the controller 208 such that the stage 202 may move in a direction as desired to etch the piezoelectric layer 106.

The scanner 204 includes a scanner actuator 212. The scanner actuator 212 allows the scanner 204 to scan in the X direction, the Y direction, and the Z direction, as indicated by the coordinate system shown in FIG. 2. The laser source 214 and the optical array 216 are disposed in or on the scanner 204. The scanner 204 is coupled to the controller 208 in order to provide information of the location of the scanner 204 to the controller 208. In one embodiment, which can be combined with other embodiments described herein, the scanner 204 is a galvo scanner.

In one embodiment, which can be combined with other embodiments described herein, the laser etching system 200 performing a method for etching may utilize both the scanner 204 and the stage 202 to direct the laser 206 toward the substrate 102. In another embodiment, which can be combined with other embodiments described herein, the laser etching system 200 performing the method for etching may utilize only the scanner 204 to direct the laser 206 toward the substrate 102. In yet another embodiment, which can be combined with other embodiments described herein, the laser etching system 200 performing the method for etching may utilize only the stage 202 to direct the laser 206 toward the substrate 102.

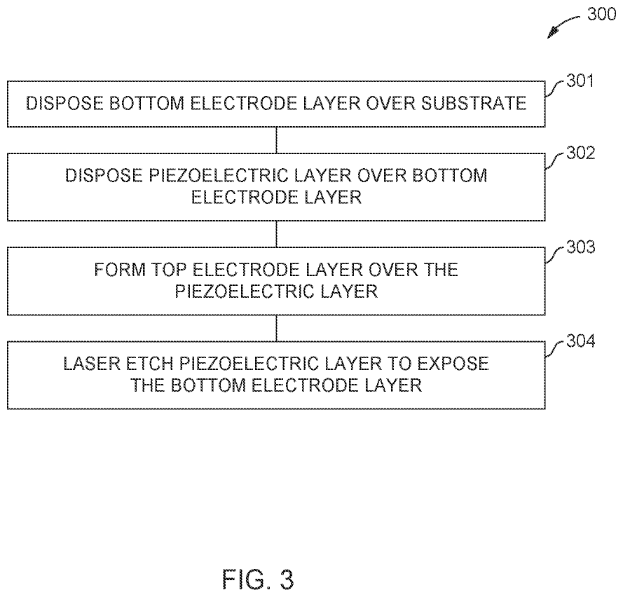

FIG. 3 is a flow diagram of a method 300 of forming a piezoelectric device 100, as shown in FIGS. 4A-4D. FIGS. 4A-4D are schematic, side views of a substrate 102 during the method 300 of forming a piezoelectric device 100. To facilitate explanation, the method 300 is described with reference to the laser etching system 200, shown in FIG. 2. However, the method 300 is not limited to the laser etching system 200 and may be performed in conjunction with any suitable laser etching system. The method 300 is operable to utilize selective laser etching to etch the piezoelectric layer 106 without damaging the bottom electrode layer 104 and other components of the piezoelectric device.

At operation 301, as shown in FIGS. 4A and 4B, a bottom electrode layer 104 is disposed over a substrate 102. The bottom electrode layer 104 is disposed via a PVD process performed in a suitable PVD chamber. In certain embodiments, the PVD process is performed between about 25° C. and about 600° C., such as between about 400° C. and about 600° C., and such as about 500° C. In certain embodiments, the target in the PVD chamber is negatively biased during the PVD process by a pulsed or continuous power supply providing a DC power with a power level between about 400 W and about 1000 W, such as between about 600 W and about 800 W.

At operation 302, as shown in FIG. 4B, a piezoelectric layer 106 is disposed over the bottom electrode layer 104. The piezoelectric layer 106 is disposed via a PVD process performed in a suitable PV chamber. In certain embodiments, the target in the PVD chamber is negatively biased by a pulsed or continuous power supply providing a RF power with a power level between about 250 W and about 1000 W.

At operation 303, as shown in FIG. 4C, a top electrode layer 108 is formed over the piezoelectric layer 106. The top electrode layer 108 is formed with a top electrode pattern 110. The top electrode layer 108 can be formed at one or more pre-determined locations over the piezoelectric surface 107. In one embodiment, which can be combined with other embodiments described herein, the top electrode layer 108 is deposited on the piezoelectric layer 106 followed by an etch process to form the top electrode pattern 110. In another embodiment, which can be combined with other embodiments described herein, the top electrode layer 108 is sputtered through a proximity mask to form the top electrode pattern 110. Multiple top electrode patterns 110 can be formed over the piezoelectric layer 106. The top electrode pattern 110 is not limited to the patterns shown in FIGS. 4C and 4D.

At operation 304, as shown in FIG. 4D, the piezoelectric layer 106 is selectively etched via laser etching. The substrate 102 may be moved or transferred to a laser etching system 200, as shown in FIG. 2, prior to the operation 304. The laser etching system 200 includes a laser 206 configured to etch the piezoelectric layer 106. The piezoelectric layer 106 is etched to form exposed portions 112 of the bottom electrode layer 104. The exposed portions 112 allow access to the bottom electrode layer 104. The piezoelectric layer 106 is selectively etched such that the bottom electrode layer 104 and the top electrode layer 108 are not unintentionally damaged during etching. Accidental etching of the bottom electrode layer 104 can permanently damage the piezoelectric device 100 to be formed. As such, the etching process stops once the piezoelectric layer 106 is removed from the piezoelectric surface 107. The exposed portions 112 are formed in order to provide electrical contact for piezoelectric devices to be formed. The piezoelectric device 100, shown in FIG. 1, is formed when the exposed portions 112 of the bottom electrode layer 104 are formed.

An exposed portion length 114 is defined by the size of exposed portions 112. The exposed portion length 114 may also correspond to a diameter of the exposed portion 112. The exposed portion length 114 is between about 100 μm and about 1000 μm. Although the shape of the exposed portions 112 are shown as circular in FIG. 1 and FIG. 4D, the shape of the exposed portions 112 are not limited and may be any pattern or shape that is pre-determined to enable high quality electrical contact to the bottom electrode layer 104. For example, the exposed portions 112 are circular, rectangular, square, or irregular in shape.

The laser etching system 200 is configured specifically to etch the piezoelectric layer 106 without damaging the bottom electrode layer 104 and the top electrode layer 108. The laser etching system 200 etches the piezoelectric layer 106 at an etch rate between about 100 μm/min and about 10 μm/min. The laser etching system 200 is further configured such that the laser 206 selectively etches only the piezoelectric layer 106 without damaging the top electrode layer 108 and the bottom electrode layer 104. The laser etching system 200 etches with a power between about 20 W and about 50 W. The laser 206 has a beam diameter of about 40 μm to about 100 μm. The laser etching system 200 etches with a frequency of about 100 Hz to about 500 Hz. The laser 206 is provided with a wavelength of about 1300 nm to about 1550 nm. The piezoelectric layer 106 is etched at an etching time of about 1 sec to about 10 sec.

In some embodiments, which can be combined with other embodiments described herein, the top electrode layer 108 is formed after etching the piezoelectric layer 106. In other embodiments, which can be combined with other embodiments, testing of the piezoelectric device 100 may be performed to ensure suitable contact through the exposed portions 112 for device characterizations. For example, electrical probe tests are run to check electrical continuity.

In yet another embodiment, which can be combined with other embodiments described herein, the piezoelectric device 100 may undergo further processing to further characterize the piezoelectric device 100. For example, dielectric measurements will be taken after the laser etching.

Utilizing the laser etching system 200 to etch the piezoelectric layer 106 to form the exposed portions 112 is advantageous by removing extra processing steps or post-processing steps (e.g., photoresist deposition steps) to remove the piezoelectric layer 106. As such, throughput of piezoelectric device 100 fabrication is increased. Additionally, the etching process described herein does not release hazardous byproducts that may be produced by other fabricating techniques.

In summary, piezoelectric devices and methods of patterning piezoelectric layers for piezoelectric device fabrication are provided herein. Piezoelectric materials are brittle and surrounding materials should not be damaged when removal of the piezoelectric materials is necessary. To expose portions of the bottom electrode layer, a laser etching technique may be used on the piezoelectric material layer. Utilizing the laser etching system to etch the piezoelectric layer to form the exposed portions is advantageous by removing extra processing steps to increase throughput and decrease hazardous byproduct output.

While the foregoing is directed to embodiments of the present disclosure, other and further embodiments of the disclosure may be devised without departing from the basic scope thereof, and the scope thereof is determined by the claims that follow.

What is claimed is:

1. A method of forming a piezoelectric device, comprising:
disposing a bottom electrode layer over a substrate via physical vapor deposition (PVD);
disposing a piezoelectric layer over the bottom electrode layer via PVD;
forming a top electrode layer with a top electrode pattern over the piezoelectric layer; and
etching the piezoelectric layer via laser etching to form exposed portions of the bottom electrode layer to form the piezoelectric device.

2. The method of claim 1, wherein the laser etching selectively etches only the piezoelectric layer without damaging the top electrode layer and the bottom electrode layer.

3. The method of claim 1, wherein the laser etching is provided with a power between about 20 W and about 50 W.

4. The method of claim 1, wherein a laser utilized for the laser etching has a beam diameter of about 40 μm to about 100 μm.

5. The method of claim 1, wherein the laser etching is provided with a frequency of about 100 Hz to about 500 Hz.

6. The method of claim 1, wherein the piezoelectric layer includes one or more of aluminum nitride (AlN), scandium-doped aluminum nitride (ScAlN), lead zirconate titanate (PZT), lead magnesium niobate-lead titanate (PMN-PT), and LiNbO₃ (LNO).

7. The method of claim 1, wherein the laser etching is provided with a wavelength of about 1300 nm to about 1550 nm.

8. The method of claim 1, wherein the piezoelectric layer is etched at an etching time of about 1 sec to about 10 sec.

9. The method of claim 1, wherein the laser etching includes an optical fiber laser.

10. The method of claim 1, wherein the top electrode layer is formed via sputtering through a proximity mask.

11. A method of forming a piezoelectric device, comprising:
disposing a bottom electrode layer over a substrate via physical vapor deposition (PVD);
disposing a piezoelectric layer over the bottom electrode layer via PVD, wherein the piezoelectric layer includes an aluminum nitride (AlN) or scandium-doped aluminum nitride (ScAlN) material;
forming a top electrode layer with a top electrode pattern over the piezoelectric layer; and
etching the piezoelectric layer via laser etching to form exposed portions of the bottom electrode layer, wherein the laser etching occurs with an etch rate of about 100 μm/min to about 10 μm/min.

12. The method of claim 11, wherein the piezoelectric layer is selectively etched.

13. The method of claim 12, wherein the laser etching selectively etches only the piezoelectric layer without damaging the top electrode layer and the bottom electrode layer.

14. A piezoelectric device, comprising:
a substrate;
a bottom electrode layer formed over the substrate;
a piezoelectric layer formed over the bottom electrode layer, the piezoelectric layer including an aluminum nitride (AlN) or scandium-doped aluminum nitride (ScAlN) material, wherein exposed portions of the bottom electrode layer are formed via laser etching the piezoelectric layer; and
a top electrode layer formed on the piezoelectric layer.

15. The piezoelectric device of claim 14, wherein the exposed portions have an exposed portion length between about 100 μm and about 1000 μm.

16. The piezoelectric device of claim 14, wherein the exposed portions of the bottom electrode layer are circular, rectangular, square, or irregular in shape.

17. The piezoelectric device of claim 14, wherein the piezoelectric layer includes an aluminum nitride (AlN) material.

18. The piezoelectric device of claim 14, wherein the piezoelectric layer includes a scandium-doped aluminum nitride (ScAlN).

19. The piezoelectric device of claim 14, wherein the substrate is a silicon containing material.

20. The piezoelectric device of claim 14, wherein the bottom electrode layer includes platinum (Pt) or molybdenum (Mo).
